(19) United States
(12) Patent Application Publication
(10) Pub. No.: US 2002/0168818 A1
(43) Pub. Date: Nov. 14, 2002

(54) Method to manufacture a split gate P+ EEPROM memory cell

(76) Inventor: Albert Bergemont, Palo Alto, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/855,477

(22) Filed: May 14, 2001

(51) Int. Cl. H01L 21/336

(52) U.S. Cl. 438/257; 438/954

(57) ABSTRACT

A method of forming a split gate EEPROM memory cell which has exclusively a thermally-grown oxide separating a side of a floating gate from an opposing side of a control gate, and separating the control gate from the underlying substrate. The method includes the steps of forming a doped polysilicon floating gate over a first portion of a channel, forming an oxide-nitride-oxide (ONO) dielectric over the doped polysilicon floating gate, oxidizing a side of the doped polysilicon floating gate to form a thermally-grown silicon dioxide (SiO₂) dielectric, and forming a control gate over a second portion of the channel, wherein the thermally-grown silicon dioxide (SiO₂) dielectric is interposed between the floating gate and the control gate. An alternative implementation of a method adds another silicon nitride layer on top of the ONO dielectric to protect the underlying oxide from a cleaning process.

### FIELD OF THE INVENTION

This invention relates generally to semiconductor processing, and in particular, to a method of forming a split gate electrically erasable programmable read only memory (EEPROM) memory cell having a thermally grown oxide separating the control gate from the floating gate and the control gate from the substrate.

### BACKGROUND OF THE INVENTION

A typical split gate electrically erasable programmable read only memory (EEPROM) comprises a p-substrate with an n-well having spaced apart drain and source regions. A current conducting channel is defined between the drain and source regions. A floating gate is situated over a first portion of the channel and separated therefrom by a thin oxide. A control gate is situated over a second portion of the channel and separated therefrom by a thin oxide. The control gate may extend over the floating gate separated therefrom by a dielectric layer.

Typically, a thin dielectric layer is situated between the sides of the floating gate and the control gate. In the prior art, this thin dielectric layer is a combination of a deposited oxide and a thermal oxide. Deposited oxides are typically not as reliable as thermal oxides. For EEPROM applications, it is desirable to have a highly reliable oxide separating the floating gate from the control gate since the voltage difference across these two structures may be relatively high during programming and erasing operations.

Thus, there is a need for a method of forming a split gate EEPROM memory cell which has a higher reliable dielectric separating the floating gate from the control gate. Such a need and others are met with the method of forming a split gate EEPROM memory cell in accordance with the invention.

### SUMMARY OF THE INVENTION

An aspect of the invention relates to a method of forming a split gate electrically erasable programmable read only memory (EEPROM) memory cell which has exclusively a thermally-grown oxide separating a side of a floating gate from an opposing side of a control gate, and separating the control gate from the underlying substrate. This is advantageous because thermally grown oxides are more reliable dielectrics than deposited oxides or a combination of deposited oxides and thermally-grown oxides.

The method of forming the memory cell in accordance with the invention comprises forming a doped polysilicon floating gate over a first portion of a channel situated within a substrate between drain and source regions, forming an oxide-nitride-oxide (ONO) dielectric over the doped polysilicon floating gate, oxidizing a side of the doped polysilicon floating gate to form a thermally-grown silicon dioxide (SiO₂) dielectric, and forming a control gate over a second portion of the channel, wherein the thermally-grown silicon dioxide (SiO₂) dielectric is interposed between the floating gate and the control gate, and between the control gate and the substrate.

An alternative implementation of the method of forming a memory cell comprises the steps of forming a doped polysilicon floating gate over a first portion of a channel situated within a substrate between drain and source region, forming an oxide-nitride-oxide-nitride (ONON) dielectric over the doped polysilicon floating gate, oxidizing a side of the doped polysilicon floating gate to form a thermally-grown silicon dioxide (SiO₂) dielectric, and forming a control gate over a second portion of the channel, wherein the thermally-grown silicon dioxide (SiO₂) dielectric is interposed between floating gate and the control gate.

Other aspects, features and techniques of the invention will become apparent to one skilled in the relevant art in view of the following detailed description of the invention.

### BRIEF DESCRIPTION OF THE DRAWINGS

FIG. 1 illustrates a cross-sectional view of an exemplary semiconductor device at an intermediate step of an exemplary method of forming a split gate electrically erasable programmable read only memory (EEPROM) memory cell in accordance with the invention;

FIG. 2 illustrates a cross-sectional view of the exemplary semiconductor device at a subsequent step of the exemplary method of forming a split gate EEPROM memory cell in accordance with the invention;

FIG. 3 illustrates a cross-sectional view of the exemplary semiconductor device at a subsequent step of the exemplary method of forming a split gate EEPROM memory cell in accordance with the invention;

FIG. 4 illustrates a cross-sectional view of the exemplary semiconductor device at a subsequent step of the exemplary method of forming a split gate EEPROM memory cell in accordance with the invention;

FIG. 5 illustrates a cross-sectional view of the exemplary semiconductor device at a subsequent step of the exemplary method of forming a split gate EEPROM memory cell in accordance with the invention;

FIG. 6 illustrates a cross-sectional view of the exemplary semiconductor device at a subsequent step of the exemplary method of forming a split gate EEPROM memory cell in accordance with the invention; and

FIG. 7 illustrates a cross-sectional view of the exemplary semiconductor device at a subsequent step of the exemplary method of forming a split gate EEPROM memory cell in accordance with the invention.

### DETAILED DESCRIPTION OF THE INVENTION

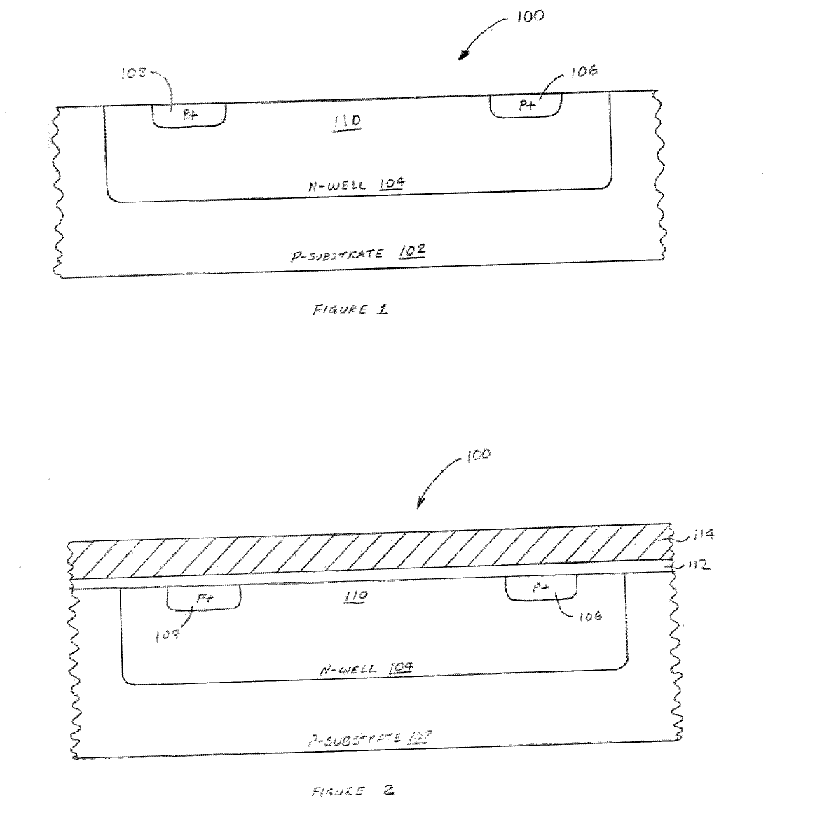

FIG. 1 illustrates a cross-sectional view of an exemplary semiconductor device 100 at an intermediate step of an exemplary method of forming a split gate electrically erasable programmable read only memory (EEPROM) memory cell in accordance with the invention. At this intermediate step, the semiconductor device 100 comprises a p-doped silicon substrate 102, an n-well 104 formed within the substrate 102, a drain p+ contact region 106 formed within the n-well 104, and a source p+ contact region 108 also formed within the n-well 104 and spaced apart from the drain p+ contact region 106. A channel 110 through which current conducts is defined between the drain and source regions 106 and 108.

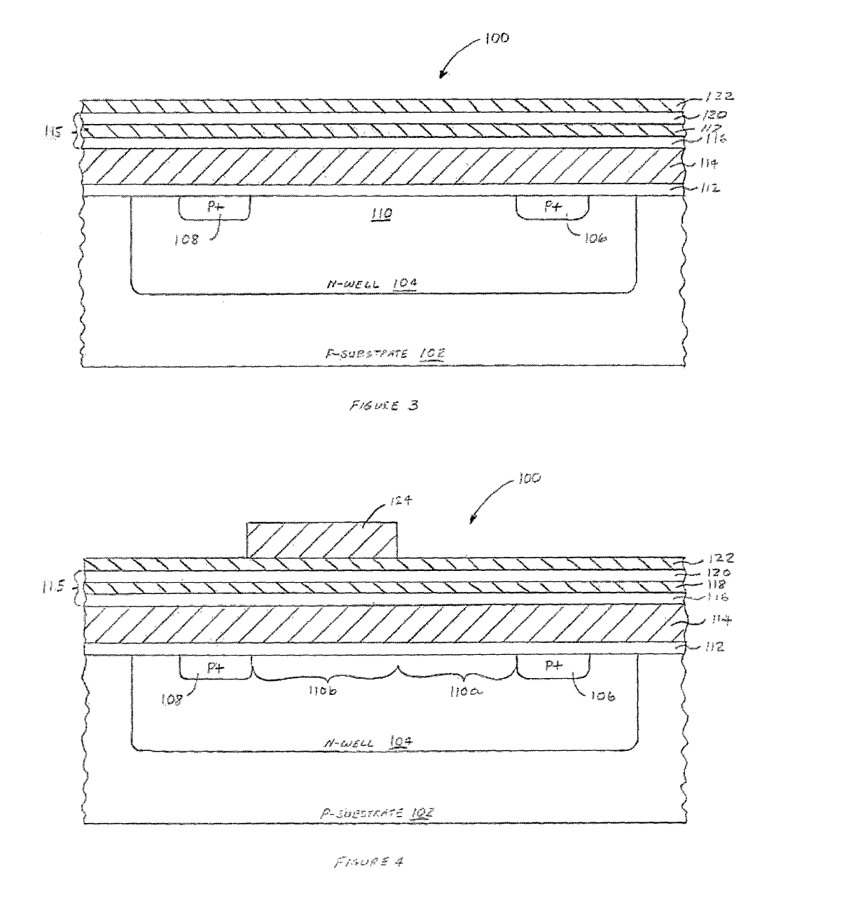

FIG. 2 illustrates a cross-sectional view of the exemplary semiconductor device 100 at a subsequent step of the exemplary method of forming a split gate EEPROM memory cell in accordance with the invention. At this subsequent step, a layer of silicon dioxide (SiO₂) 112 layer is formed over the p-substrate 102. In the exemplary method, the silicon dioxide (SiO₂) layer 112 is formed by thermally growing silicon to a thickness as low as 20 Angstroms, but typically about 90 to 110 Angstroms. Also, a doped poly crystalline silicon (“polysilicon”) layer 114 is formed over the silicon dioxide (SiO₂) layer 112. The doped polysilicon layer 114 may be doped in-situ while the polysilicon material is being deposited, or may be doped after the polysilicon material has been deposited. The doped polysilicon layer 114 may be deposited to a thickness of about 3000 Angstroms.

FIG. 3 illustrates a cross-sectional view of the exemplary semiconductor device 100 at a subsequent step of the exemplary method of forming a split gate EEPROM memory cell in accordance with the invention. In this subsequent step, an oxide-nitride-oxide (ONO) stack 115 is formed over the doped polysilicon layer 114. In forming the oxide-nitride-oxide (ONO) stack 115, a second layer of silicon dioxide (SiO₂) 116 is deposited to achieve a thickness of about 90 to 110 Angstroms and then subsequently annealed. Then, a layer of silicon nitride (Si₃N₄) 118 is deposited over the second silicon dioxide (SiO₂) layer 116 to achieve a thickness of about 90 to 110 Angstroms. After this, a third layer of silicon dioxide (SiO₂) 120 is deposited to achieve a thickness of about 90 to 110 Angstroms and then subsequently annealed.

As an option, a second layer of silicon nitride (Si₃N₄) 122 may be deposited over the third silicon dioxide (SiO₂) layer 120 to a thickness of about 90 to 110 Angstroms. This second silicon nitride (Si₃N₄) layer 122 protects the underlying silicon dioxide (SiO₂) layer 120 from erosion due to subsequent cleaning steps.

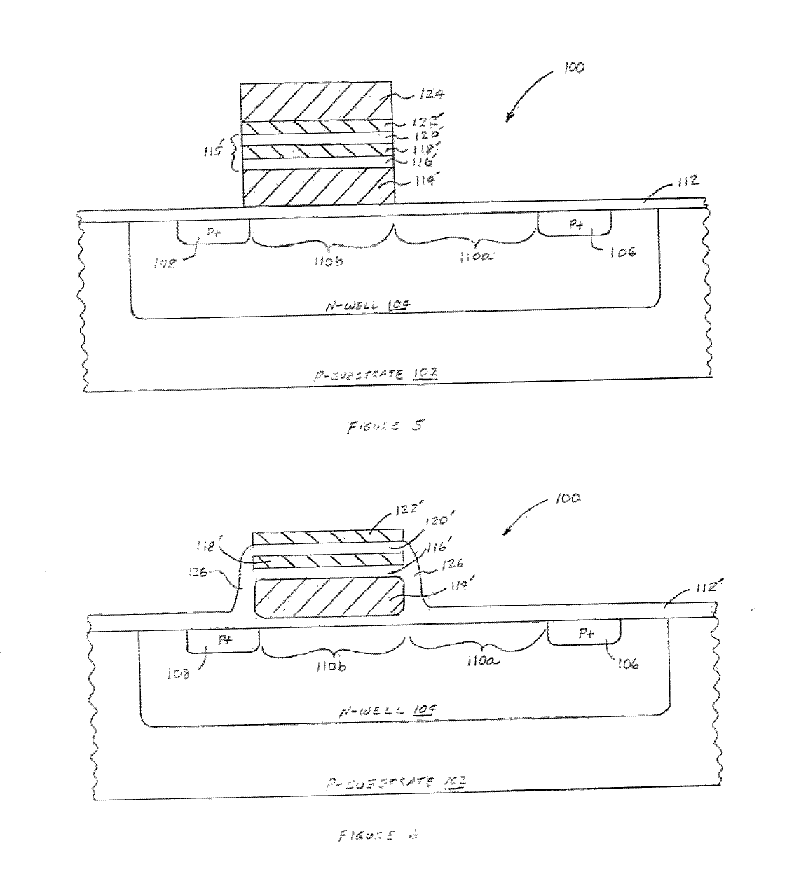

FIG. 4 illustrates a cross-sectional view of the exemplary semiconductor device 100 at a subsequent step of the exemplary method of forming a split gate EEPROM memory cell in accordance with the invention. In this subsequent step, a layer of photo resist is deposited over the oxide-nitride-oxide (ONO) stack 115 (or optionally over the second silicon nitride (Si₃N₄) layer 122) and subsequently patterned to form photo resist mask 124 which will define the floating gate overlying a portion 110b of the memory cell channel 110.

FIG. 5 illustrates a cross-sectional view of the exemplary semiconductor device 100 at a subsequent step of the exemplary method of forming a split gate EEPROM memory cell in accordance with the invention. In this subsequent step, the second silicon nitride (Si₃N₄) layer 122 (if optionally present), the oxide-nitride-oxide (ONO) stack 115, and the doped polysilicon layer 114 is etched off, except under the photo resist mask 124. After the etching process, a doped polysilicon floating gate 114′ is formed over the first silicon dioxide (SiO₂) layer 112 above the portion 110b of the channel 110. Also formed is an oxide-nitride-oxide (ONO) dielectric 115′ that overlies the floating gate 114′. The oxide-nitride-oxide (ONO) dielectric 115′ comprises a bottom silicon dioxide (SiO₂) layer 116′, a middle silicon nitride (Si₃N₄) layer 118′, and a top silicon dioxide (SiO₂) layer 120′. Optionally, a top silicon nitride (Si₃N₄) dielectric 122′ may be formed over the oxide-nitride-oxide (ONO) dielectric 115′.

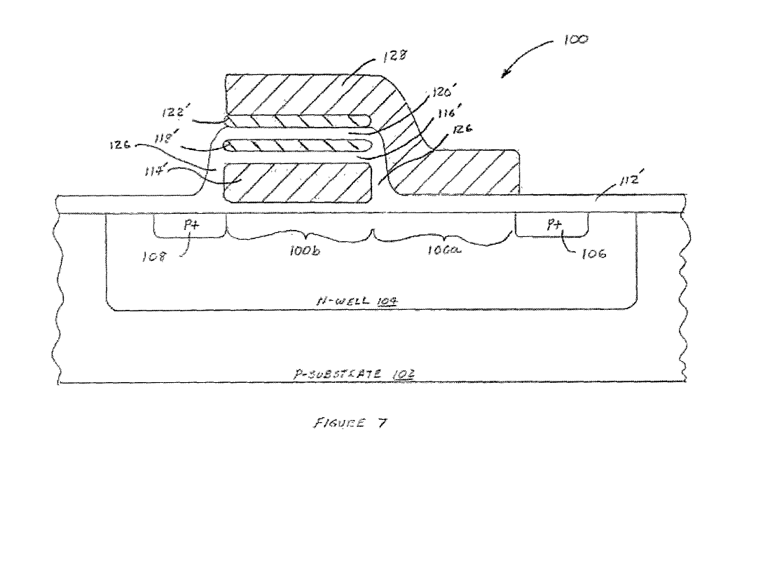

FIG. 6 illustrates a cross-sectional view of the exemplary semiconductor device 100 at a subsequent step of the exemplary method of forming a split gate EEPROM memory cell in accordance with the invention. In this subsequent step, the photo resist mask 124 is striped off and the semiconductor device 100 is subjected to a cleaning process. Then, the semiconductor device 100 is subjected to an oxidation process to oxidize the side regions of the polysilicon floating gate 114′ and the side regions of the top and bottom silicon dioxide (SiO₂) layer 120′ and 116′, and the first silicon dioxide (SiO₂) layer 112. This process forms a thermally grown silicon dioxide (SiO₂) dielectric 126 on the sides of the floating gate 114′. The lateral thickness of the thermally-grown silicon dioxide (SiO₂) dielectric 126 may be approximately 300 to 800 Angstroms. This process also forms a thicker (e.g. 300 to 800 Angstroms) thermally grown silicon dioxide (SiO₂) dielectric 112′ over the substrate 102 above the portion 110a of the memory cell channel 110. These dielectrics 126 and 112′ electrically isolate the to-be-formed control gate from the floating gate 114′ and the substrate 102. Since these dielectrics 126 and 112′ are exclusively thermally grown, they are more reliable than dielectrics formed by deposited oxides or a combination of deposited oxides and thermally-grown oxides.

FIG. 7 illustrates a cross-sectional view of the exemplary semiconductor device 100 at a subsequent step of the exemplary method of forming a split gate EEPROM memory cell in accordance with the invention. In this step, the doped polysilicon control gate 128 is formed over the thermally grown silicon dioxide (SiO₂) dielectric 112′ above the portion 110a of the memory cell channel 110, and optionally above the oxide-nitride-oxide (ONO) dielectric 115′ and above the top silicon nitride (Si₃N₄) dielectric 122′ if present.

In the foregoing specification, the invention has been described with reference to specific embodiments thereof. It will, however, be evident that various modifications and changes may be made thereto departing from the broader spirit and scope of the invention. The specification and drawings are, accordingly, to be regarded in an illustrative rather than a restrictive sense.

It is claimed:

1. A method of forming a memory cell, comprising:
forming a doped polysilicon floating gate over a first portion of a channel situated within a substrate between drain and source regions;
forming an oxide-nitride-oxide (ONO) dielectric over said doped polysilicon floating gate;
oxidizing a side region of said doped polysilicon floating gate to form a thermally-grown silicon dioxide (SiO₂) dielectric; and
forming a control gate over a second portion of said channel, wherein said thermally-grown silicon dioxide (SiO₂) dielectric is interposed between said floating gate and said control gate.

2. The method of claim 1, wherein forming said doped polysilicon floating gate comprises:
depositing a layer of polysilicon material;
doping said layer of polysilicon material; and
etching a portion of said deposited polysilicon material to form said floating gate.

3. The method of claim 2, wherein doping said layer of polysilicon material is performed in situ while said polysilicon material is being deposited.

4. The method of claim 1, wherein forming said oxide-nitride-oxide (ONO) dielectric comprises:
depositing a first layer of silicon dioxide (SiO₂) material;
annealing said first layer of silicon dioxide (SiO₂) material;
depositing a layer of silicon nitride (Si₃N₄) material over said first silicon dioxide (SiO₂) layer;
depositing a second layer of silicon dioxide (SiO₂) over said silicon nitride (Si₃N₄) layer;
annealing said second layer of silicon dioxide (SiO₂); and
etching respective portions of said first silicon dioxide (Si0₂) layer, said silicon nitride (Si₃N₄) layer, and said second silicon dioxide (SiO₂) layer to form said oxide-nitride-oxide (ONO) dielectric.

5. The method of claim 1, wherein oxidizing said side region of said polysilicon floating gate comprises oxidizing said side region of said polysilicon floating gate along with a corresponding side of said oxide-nitride-oxide (ONO) dielectric to form said thermally-grown silicon dioxide (SiO₂) dielectric.

6. The method of claim 1, wherein a lateral thickness of said thermally-grown silicon dioxide (SiO₂) dielectric is approximately 300 to 800 Angstroms.

7. The method of claim 1, wherein forming said control gate comprises:
forming a layer of polysilicon material;
doping said polysilicon material layer; and
etching said polysilicon material layer to form said control gate.

8. The method of claim 1, further comprising forming a silicon dioxide (SiO₂) layer under said floating gate and said control gate.

9. The method of claim 8, wherein oxidizing said side region of said doped polysilicon floating gate also oxidizes said silicon dioxide (SiO₂) layer to increase its thickness.

10. The method of claim 9, wherein said increase in thickness of said silicon dioxide (SiO₂) layer is from approximately 20 Angstroms to a range of approximately 300 to 800 Angstroms.

11. A method of forming a memory cell, comprising:
forming a doped polysilicon floating gate over a first portion of a channel situated within a substrate between drain and source regions;
forming an oxide-nitride-oxide-nitride (ONON) dielectric over said doped polysilicon floating gate;
oxidizing a side region of said doped polysilicon floating gate to form a thermally-grown silicon dioxide (SiO₂) dielectric; and
forming a control gate over a second portion of said channel, wherein said thermally-grown silicon dioxide (SiO₂) dielectric is interposed between said floating gate and said control gate.

12. The method of claim 11, wherein forming said doped polysilicon floating gate comprises:
depositing a layer of polysilicon material;
doping said layer of polysilicon material; and
etching a portion of said deposited polysilicon material to form said floating gate.

13. The method of claim 12, wherein doping said layer of polysilicon material is performed in situ while said polysilicon material is being deposited.

14. The method of claim 11, wherein forming said oxide-nitride-oxide-nitride (ONON) dielectric comprises:
depositing a first layer of silicon dioxide (SiO₂) material;
annealing said first layer of silicon dioxide (SiO₂) material;
depositing a first layer of silicon nitride (Si₃N₄) material over said first silicon dioxide (SiO₂) layer;
depositing a second layer of silicon dioxide (SiO₂) over said first silicon nitride (Si₃N₄) layer;
annealing said second layer of silicon dioxide (SiO₂);
depositing a second layer of silicon nitride (Si₃N₄) over said second silicon dioxide (SiO₂) layer; and
etching respective portions of said first silicon dioxide (SiO₂) layer, said second silicon nitride (Si₃N₄) layer, said second silicon dioxide (SiO₂) layer, and said second silicon nitride (Si₃N₄) layer to form said oxide-nitride-oxide-nitride (ONON) dielectric.

15. The method of claim 11, wherein oxidizing said side region of said polysilicon floating gate comprises oxidizing said side region of said polysilicon floating gate along with a corresponding side of said oxide-nitride-oxide-nitride (ONON) dielectric to form said thermally-grown silicon dioxide (SiO₂) dielectric.

16. The method of claim 11, wherein a lateral thickness of said thermally-grown silicon dioxide (SiO₂) dielectric is approximately 300 to 800 Angstroms.

17. The method of claim 11, wherein forming said control gate comprises:
forming a layer of polysilicon material;
doping said polysilicon material layer; and
etching said polysilicon material layer to form said control gate.

18. The method of claim 11, further comprising forming a silicon dioxide (SiO₂) layer under said floating gate and said control gate.

19. The method of claim 18, wherein oxidizing said side region of said doped polysilicon floating gate also oxidizes said silicon dioxide (SiO₂) layer to increase its thickness.

20. The method of claim 19, wherein said increase in thickness of said silicon dioxide (SiO₂) layer is from approximately 20 Angstroms to a range of approximately 300 to 800 Angstroms.
